(19) United States
(12) Patent Application Publication
(10) Pub. No.: US 2026/0198376 A1
(43) Pub. Date: Jul. 9, 2026

(54) ELASTOMERIC BARRIER FOR A THERMAL INTERFACE MATERIAL IN AN ELECTRONIC DEVICE

(71) Applicant: NVIDIA CORPORATION, Santa Clara, CA (US)

(72) Inventors: Malcolm GUTENBURG, San Francisco, CA (US); Jungho NA, Milpitas, CA (US); Cole LINNUS, San Francisco, CA (US); Yunseok KIM, Pleasanton, CA (US)

(21) Appl. No.: 19/009,649

(22) Filed: Jan. 3, 2025

(51) Int. Cl. H01L 23/00; H01L 23/10; H01L 23/373; H01L 25/16

(52) U.S. Cl. CPC H10W 90/00; H10W 40/25; H10W 76/60; H10W 72/352; H10W 72/387; H10W 90/731

(57) ABSTRACT

One embodiment sets forth an electronic device that includes a printed circuit board, an integrated circuit that is coupled to the printed circuit board on a first side and a thermal solution on a second side, a thermal interface material that is disposed between the integrated circuit and the thermal solution, and an elastomeric sealing member that is disposed around a perimeter of the integrated circuit.

### BACKGROUND

### Field of the Various Embodiments

Embodiments of the present invention relate generally to computer systems and, more specifically, to an elastomeric barrier for a thermal interface material in an electronic device.

### Description of the Related Art

In modern computing devices, central processing units (CPUs), graphics processing units (GPUs), and other integrated circuits (ICs) generate significant quantities of heat during operation. For example, a single high-power chip, such as a CPU or a GPU, can generate hundreds of watts of heat during operation. This heat needs to be removed from the chip and the computing device to prevent thermal damage from occurring. To prevent thermal damage during operation, many computing devices implement clock-speed throttling when the operating temperature of a chip exceeds a certain threshold. Therefore, the overall performance of the chip is constrained by both the design of the chip and how effectively heat is removed from the chip during operation.

Heatsinks are commonly employed to effectively dissipate heat that is produced when chips operate at greater processing speeds and power levels. As is well-understood, a heatsink transfers heat from a chip to another medium, such the surrounding air, which then carries the heat away from the chip and out of the computing device. To facilitate thermal conduction between the chip and the heatsink, a thermal interface material (TIM) is often disposed between the top surface of the chip and the bottom surface of the heatsink.

As the computational performance capacities of chips increase, the TIM can become a limiting factor in how effectively such chips can be cooled using attached heatsinks. In particular, the thermal conductivity and thickness of the TIM can affect how well the TIM transfers thermal energy from a given chip to an attached heatsink. For example, increasing the thermal conductivity and reducing the thickness of TIMs can increase the thermal and computational performance of chips. The use of liquid-metal TIMs, such as materials that include high amounts of gallium, indium, and tin, have been found to have increased thermal conductivity performance and reduced thickness requirements compared to previous types of TIMs. As a result, liquid-metal TIMs have enabled the thermal and computational performance of chips to be improved.

One drawback of liquid-metal TIMs, however, is that liquid-metal TIMs are electrically conductive and can cause electrical shorting when the liquid-metal TIM begins to expand beyond the boundaries of the top surface of the chip and the bottom surface of the heatsink. In one example, the expansion can occur as the liquid-metal TIM is repeatedly heated and cooled throughout the operation of the chip. In another example, the expansion can occur when too much liquid-metal TIM is disposed on the surface of the chip prior to installing the heatsink, and/or when too much pressure is applied between the top surface of the chip and the bottom surface of the heatsink when installing the heatsink onto the chip. When such an expansion occurs, the electrical components that are mounted on the same packaging substrate as the chip can come into contact with excess or leaked liquid-metal TIM, which can create electrical shorts that can damage or destroy the electrical components.

Another drawback of liquid-metal TIMs is that, during operation in high-humidity, high-temperature, etc., environments, liquid-metal TIMs can be oxidized or otherwise chemically degraded by exposure to moisture and/or oxygen. For example, gallium-indium-tin-based TIMs are known to form gallium hydroxide in the presence of humidity. This type of chemical degradation can substantially reduce the thermal conductivity of the liquid-metal TIM, which, in turn, can reduce the total thermal performance of the heatsink that is coupled to the chip via the liquid-metal TIM.

As the foregoing illustrates, what is needed in the art are more effective techniques for employing liquid-metal TIMs to manage the heat of high-powered chips.

### SUMMARY

An electronic device comprises: a printed circuit board; an integrated circuit that is coupled to the printed circuit board on a first side and a thermal solution on a second side; a thermal interface material that is disposed between the integrated circuit and the thermal solution; and an elastomeric sealing member that is disposed around a perimeter of the integrated circuit.

At least one technical advantage of the disclosed design relative to the prior art is that the disclosed design can prevent liquid-metal TIM or other electrically conductive TIM from leaking and contacting capacitors or other electrical components that are mounted on the same packaging substrate as a high-power chip that is thermally coupled to a thermal solution via the liquid-metal TIM. Another technical advantage is that the disclosed design can enable a thermal solution to be coupled to a high-power chip with greater pressure compared to using sealing materials that typically soften during operation of the high-power chip, such as wax-based substances, low-melting-point adhesives, and/or low-temperature “hot-melt” polymers. Yet another technical advantage is that the disclosed design can reduce the exposure of a liquid-metal TIM or other TIM to moisture and/or other contaminants that can react with and alter the thermal conductivity of the liquid-metal TIM. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual cross-section of an integrated circuit mounted on a PCB and coupled to a heat sink, in accordance with the prior art.

FIG. 2 is a block diagram illustrating a computer system configured to implement one or more aspects of the various embodiments.

FIG. 3 is a conceptual cross-sectional view of an electronic device that includes a heatsink, a TIM, and an elastomeric sealing member, according to various embodiments.

FIG. 4 is a perspective view of the electronic device of FIG. 3 with the heatsink removed to show how the elastomeric sealing member can be positioned around an integrated circuit of the electronic device, according to various embodiments.

FIG. 5 is a conceptual cross-sectional view of the elastomeric sealing member of FIG. 3, according to various embodiments.

FIG. 6 is a conceptual cross-sectional view of a sealing ridge of the elastomeric sealing member of FIG. 5, according to various embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skill in the art that the inventive concepts may be practiced without one or more of these specific details.

### Overview of the Prior Art

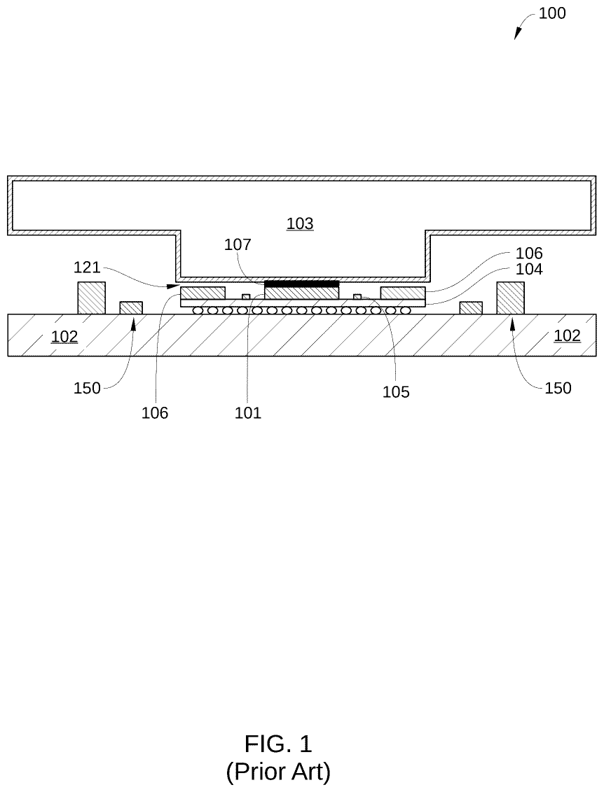

FIG. 1 is a conceptual cross-section of an integrated circuit (IC) 101 (such as a CPU, GPU, or other processor) mounted on a printed circuit board (PCB) 102 and coupled to a heat sink 103, in accordance with the prior art. Other electronic components 150 are also mounted on PCB 102, such as memory devices and/or power devices associated with IC 101. As shown, IC 101 is mounted on a packaging substrate 104, along with various other electronic components 105, such as capacitors. Frequently, a stiffener 106 is coupled to packaging substrate 104 to mechanically stiffen packaging substrate 104. Together, the above components form an electronic device 100.

IC 101 is thermally coupled to heat sink 103 via a liquid-metal thermal interface material (TIM) 107, which has excellent thermal conductivity, but also is electrically conductive. Because liquid-metal TIM 107 is not a solid material, in some instances liquid-metal TIM 107 can leak onto packaging substrate 104 and/or excess liquid-metal TIM 107 can be deposited onto packaging substrate 104. In either case, because liquid-metal TIM 107 is electrically conductive, electronic components 105 can be electrically shorted when liquid-metal TIM 107 comes in contact therewith.

FIG. 1 further shows an air gap 121 between heat sink 103 and stiffener 106 and/or packaging substrate 104. Air gap 121 is typically present so that stiffener 106 does not contact heat sink 103 even when heat sink 103, stiffener 106, and/or other components within electronic device 100 vary dimensionally within specified tolerance limits. Air gap 121 also prevents stiffener 106 from exerting pressure on heat sink 103 in a direction away from IC 101 when stiffener 106 heats up and expands. Contact between heat sink 103 and stiffener 106 and/or pressure against heat sink 103 in a direction away from IC 101 is undesirable, because heat transfer increases between heat sink 103 and IC 101 when heat sink 103 is pressed with greater force against IC 101. Conversely, such heat transfer decreases when heat sink 103 is pressed with less force against IC 101. However, the presence of air gap 121 allows humidity, oxygen, and other potential contaminants to contact liquid-metal TIM 107, which can cause oxidation of liquid-metal TIM 107 and/or other chemical degradation of liquid-metal TIM 107. For example, when liquid-metal TIM 107 is a gallium-indium-tin-based TIM, the presence of humidity adjacent to liquid-metal TIM 107 can result in the formation of gallium hydroxide, and such chemical degradation can greatly decrease the thermal conductivity of liquid-metal TIM 107. Further, the presence of air gap 121 allows liquid-metal TIM 107 that has been displaced from IC 101 to potentially reach electronic components 150 mounted on PCB 102, which can cause electrical shorting.

### Overview of Elastomeric Sealing Member Concept

According to various embodiments, an electronic device with one or more high-power ICs thermally coupled to a heatsink or other thermal solution also includes an elastomeric sealing member that is disposed around a perimeter of the one or more high-power ICs. Examples of such electronic devices include CPU cards and GPU cards. In some embodiments, the elastomeric sealing member prevents shorting that can be caused by leaking or excess liquid-metal TIM or other electrically conductive TIM that thermally couples the thermal solution to the ICs. Alternatively, or additionally, in some embodiments, the elastomeric sealing member prevents exposure of the liquid-metal TIM to humidity and/or other contaminants that can chemically react with the liquid-metal TIM. Furthermore, the elastomeric sealing member enables such advantages without compromising the thermal performance of the TIM. Examples of such embodiments are described below.

### System Overview

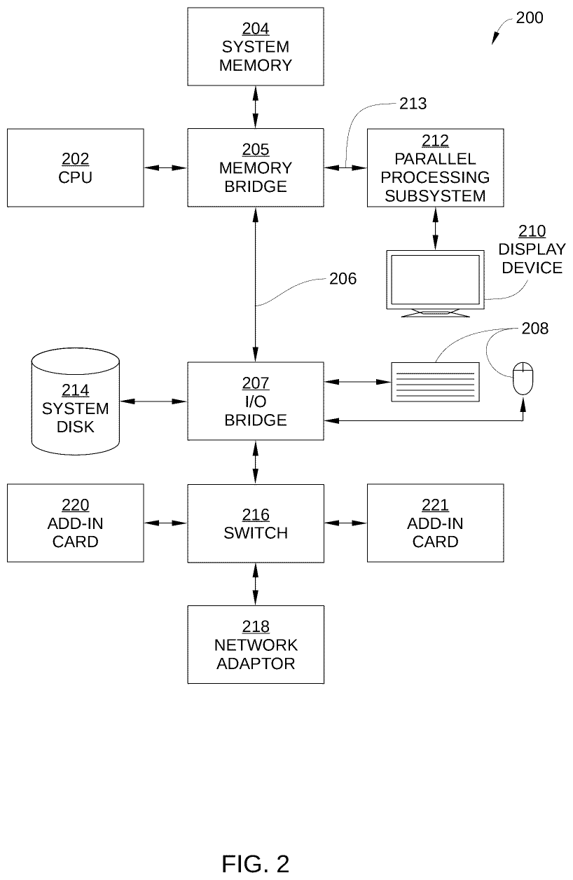

FIG. 2 is a block diagram illustrating a computer system 200 configured to implement one or more aspects of the various embodiments. As shown, computer system 200 includes, without limitation, a central processing unit (CPU) 202 and a system memory 204 coupled to a parallel processing subsystem 212 via a memory bridge 205 and a communication path 213. Memory bridge 205 is further coupled to an I/O (input/output) bridge 207 via a communication path 206, and I/O bridge 207 is, in turn, coupled to a switch 216.

In operation, I/O bridge 207 is configured to receive user input information from input devices 208, such as a keyboard or a mouse, and forward the input information to CPU 202 for processing via communication path 206 and memory bridge 205. Switch 216 is configured to provide connections between I/O bridge 207 and other components of the computer system 200, such as a network adapter 218 and various add-in cards 220 and 221.

As also shown, I/O bridge 207 is coupled to a system disk 214 that may be configured to store content and applications and data for use by CPU 202 and parallel processing subsystem 212. As a general matter, system disk 214 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid state storage devices. Finally, although not explicitly shown, other components, such as universal serial bus or other port connections, compact disc drives, digital versatile disc drives, film recording devices, and the like, may be connected to I/O bridge 207 as well.

In various embodiments, memory bridge 205 may be a Northbridge chip, and I/O bridge 207 may be a Southbrige chip. In addition, communication paths 206 and 213, as well as other communication paths within computer system 200, may be implemented using any technically suitable protocols, including, without limitation, AGP (Accelerated Graphics Port), HyperTransport, or any other bus or point-to-point communication protocol known in the art.

In some embodiments, parallel processing subsystem 212 comprises a graphics subsystem that delivers pixels to a display device 210 that may be any conventional cathode ray tube, liquid crystal display, light-emitting diode display, or the like. In such embodiments, the parallel processing subsystem 212 incorporates circuitry optimized for graphics and video processing, including, for example, video output circuitry. Such circuitry may be incorporated across one or more parallel processing units (PPUs) included within parallel processing subsystem 212. In other embodiments, the parallel processing subsystem 212 incorporates circuitry optimized for general purpose and/or compute processing. Again, such circuitry may be incorporated across one or more PPUs included within parallel processing subsystem 212 that are configured to perform such general purpose and/or compute operations. In yet other embodiments, the one or more PPUs included within parallel processing subsystem 212 may be configured to perform graphics processing, general purpose processing, and compute processing operations. In various embodiments, parallel processing subsystem 212 may be integrated with one or more of the other elements of FIG. 2 to form a single system. For example, parallel processing subsystem 212 may be integrated with CPU 202 and other connection circuitry on a single chip to form a system on chip (SoC).

It will be appreciated that the system shown herein is illustrative and that variations and modifications are possible. The connection topology, including the number and arrangement of bridges, the number of CPUs 202, and the number of parallel processing subsystems 212, may be modified as desired. For example, in some embodiments, system memory 204 is connected to CPU 202 directly rather than through memory bridge 205, and other devices communicate with system memory 204 via memory bridge 205 and CPU 202. In other alternative topologies, parallel processing subsystem 212 may be connected to I/O bridge 207 or directly to CPU 202, rather than to memory bridge 205. In still other embodiments, I/O bridge 207 and memory bridge 205 may be integrated into a single chip instead of existing as one or more discrete devices. Lastly, in certain embodiments, one or more components shown in FIG. 2 may not be present. For example, switch 216 may be eliminated, and network adapter 218 and add-in cards 220, 221 connect directly to I/O bridge 207.

### Elastomeric Sealing Member Embodiments

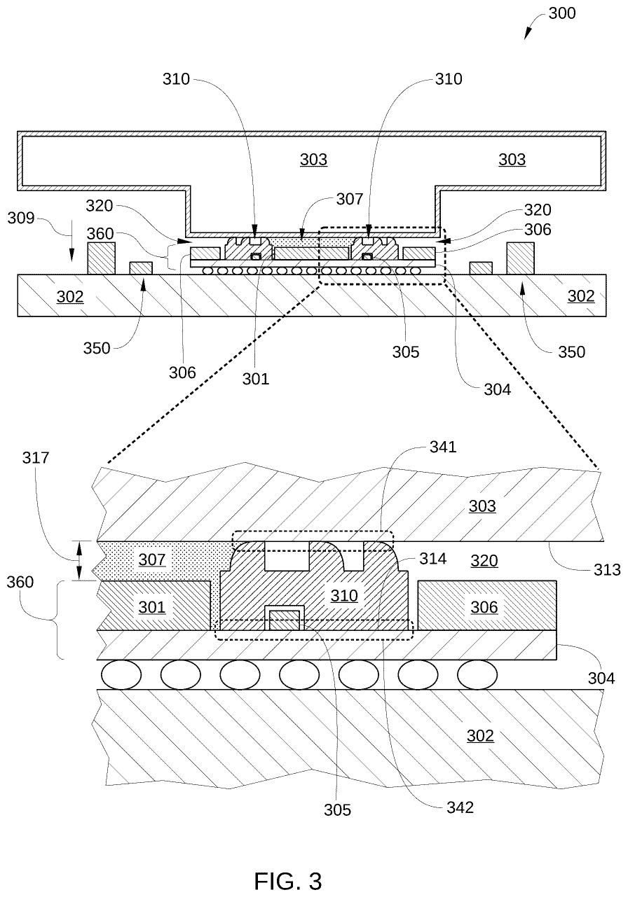

As noted above, in some embodiments, an elastomeric sealing member prevents shorting of electronic components that are proximate the high-power IC and exposure of a liquid-metal or other TIM to humidity, air, and/or other contaminants. Various embodiments are described below in conjunction with FIGS. 3-6.

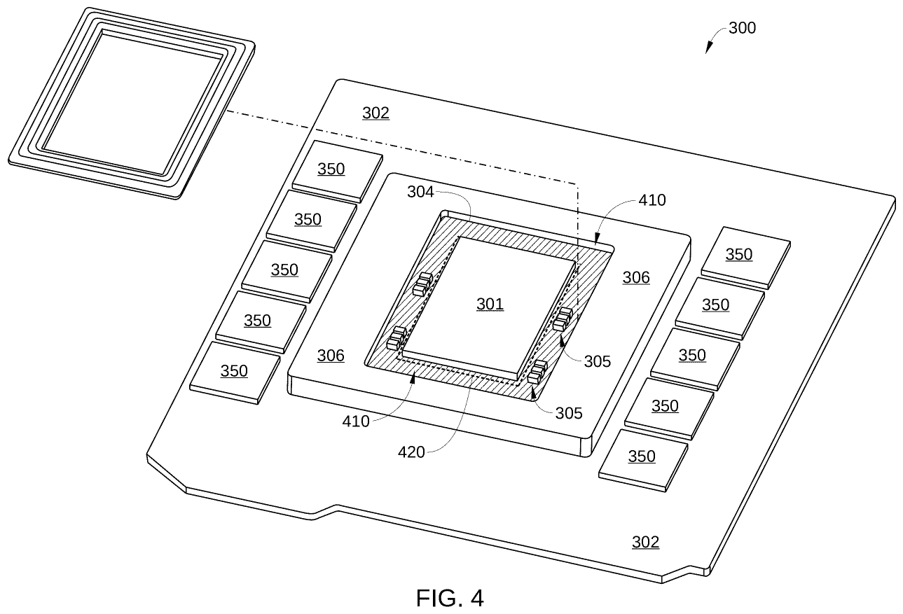

FIG. 3 is a conceptual cross-sectional view of an electronic device 300 that includes a heatsink 303, a TIM 307, and an elastomeric sealing member 310, according to various embodiments. FIG. 4 is a perspective view of electronic device 300 with heatsink 303 removed to show how elastomeric sealing member 310 can be positioned around an integrated circuit 301 of electronic device 300, according to various embodiments. In some embodiments, electronic device 300 can be implemented as CPU 202, parallel processing subsystem 212, and/or add-in cards 220, 221 in FIG. 2. In the embodiment shown in FIG. 3, IC 301 of electronic device 300 is described coupled to heatsink 303. In other embodiments, IC 301 of electronic device 300 can be coupled to any other suitable thermal solution that can be coupled to IC 301, such as a vapor chamber, a liquid cold plate, and the like.

Electronic device 300 includes IC 301 (such as a CPU, GPU, or other processor) mounted on a PCB 302 and coupled to a heatsink 303, for example via mounting screws (not shown) that press heatsink 303 against IC 301. Other electronic components 350 are also mounted on PCB 302, such as memory devices and/or power devices associated with IC 301. As shown, IC 301 is mounted on a packaging substrate 304 (cross-hatched in FIG. 4), along with various other electronic components 305, such as capacitors. In the embodiment illustrated in FIG. 3, electronic device 300 further includes a stiffener 306 that is coupled to packaging substrate 304 to mechanically stiffen packaging substrate 304 and/or an IC package 360 that includes IC 301. Together, IC 301, packaging substrate 304, and stiffener 306 form IC package 360, which is mounted on PCB 302.

IC 301 is thermally coupled to heatsink 303 via TIM 307, which can be a liquid-metal TIM, a thermal grease, or a graphene-based material. In embodiments in which TIM 307 includes a liquid-metal TIM, TIM 307 can include a liquid metal such as gallium, indium, and/or tin. In embodiments in which TIM 307 includes a graphene-based material, TIM 307 can include vertical graphene, which is a form of graphene that has high thermal and electrical conductivity, but is generally friable and subject to particle shedding. For clarity, a bond-line thickness 317 is exaggerated in direction 309 in FIG. 3. In practice, electronic device 300 is configured to minimize bond-line thickness 317 in direction 309 to facilitate heat transfer from IC 301 to heatsink 303. For example, in some embodiments, a compressive force (not shown) against heatsink 303 in direction 309 is selected to deflect elastomeric sealing member 310 a target distance in direction 309 so that bond-line thickness 317 does not exceed a threshold value.

To prevent shorting of electronic components 305 and/or any other devices mounted on packaging substrate 304 caused by excess or leaked liquid-metal of TIM 307 or electrically conductive particles of TIM 307, electronic device 300 includes elastomeric sealing member 310. As shown, elastomeric sealing member 310 is disposed within an opening 410 (shown in FIG. 4) formed in stiffener 306. In some embodiments, elastomeric sealing member 310 is an elastomeric member that is disposed around a perimeter 420 (dashed lines in FIG. 4) of IC 301 and forms an air-tight seal around IC 301. Thus, elastomeric sealing member 310 acts as a physical barrier to excess liquid-metal TIM, electrically conductive graphene particles, and/or excess thermal grease that originate from TIM 307 and can spill out or be forced away from IC 301 during assembly and/or at other times. Further, elastomeric sealing member 310 prevents humidity, oxygen, and/or other contaminants from reacting with and/or contaminating liquid-metal included in TIM 307. Consequently, in some embodiments, elastomeric sealing member 310 includes a moisture-resistant material to better form an air-tight seal around perimeter 420 of IC 301 and acts as a barrier to air and/or air-borne contaminants from reaching TIM 307. As a result, oxidation, hydrolysis, or other chemical degradation of liquid-metal included in TIM 307, or any other unwanted chemical reaction, is prevented.

Generally, elastomeric sealing member 310 can be any flexible material that can be formed into a continuous gasket or other sealing member that can be positioned in opening 410 around perimeter 420 of IC 301. In some embodiments, elastomeric sealing member 310 is formed from an elastomer that has suitable elastic properties and is compatible with the operating temperatures associated with IC 301. The specific elastic properties of elastomeric sealing member 310 that are suitable for a particular implementation of electronic device 300 can be selected based on multiple factors. For example, in some embodiments, elastomeric sealing member 310 includes an elastomer that has sufficient elasticity to compress a targeted displacement distance in direction 309 when heatsink 303 is coupled to PCB 302 and forced against a surface of IC 301. Thus, in such embodiments, the formation of a first air-tight seal 341 against heatsink 303 and a second air-tight seal 342 against packaging substrate 304 is facilitated. Additionally, or alternatively, in some embodiments, elastomeric sealing member 310 includes an elastomer that has sufficient stiffness to prevent an air gap 320 (which is disposed between heat sink 303 and stiffener 306) from closing when heatsink 303 is coupled to PCB 302 and forced toward a surface of IC 301. Thus, in such embodiments, stiffener 306 cannot push heatsink 303 away from IC 301 due to elastomeric sealing member 310 being compressed too much in direction 309. In some embodiments, elastomers suitable for forming elastomeric sealing member 310 include silicon rubber, natural rubber, styrene-butadiene rubber, nitril rubber, butyl rubber, a closed-cell foam, and a plastic or other polymer of suitable elastic properties and thermal compatibility. In some embodiments, elastomeric sealing member 310 comprises an electrically insulative material.

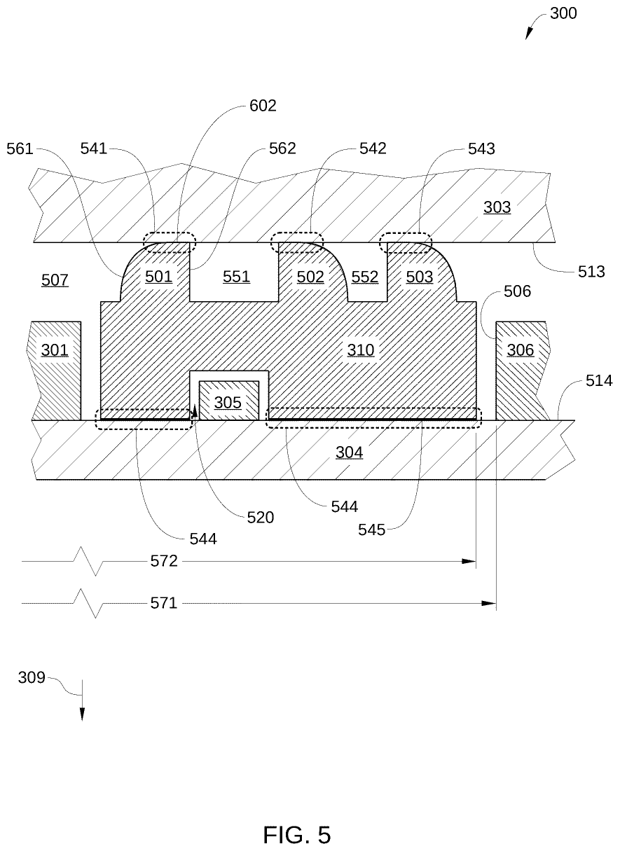

To act as a barrier to air-borne contaminants, elastomeric sealing member 310 is formed entirely and continuously around perimeter 420 of IC 301. As a result, when heatsink 303 is coupled to PCB 302 and IC 301, elastomeric sealing member 310 forms at least one continuous and air-tight seal around perimeter 420 of IC 301. For example, in some embodiments, elastomeric sealing member 310 forms at least a first air-tight seal 341 against a surface 313 of heatsink 303 and a second air-tight seal 342 against a surface 314 of packaging substrate 304. In some embodiments, elastomeric sealing member 310 includes one or more features that facilitate the formation of first air-tight seal 341 and/or second air-tight seal 342. Such embodiments are described below in conjunction with FIG. 5.

FIG. 5 is a conceptual cross-sectional view of elastomeric sealing member 310, according to various embodiments. Also shown in FIG. 5 are a portion of heatsink 303, a portion of packaging substrate 304, a portion of stiffener 306, and an electronic component 305 that is mounted on packaging substrate 304 proximate to IC 301, such as a capacitor. In some embodiments, elastomeric sealing member 310 includes at least one sealing ridge 501 that forms an air-tight seal 541 against a surface 513 of heatsink 303 that extends around perimeter 420 of IC 301.

In the embodiment illustrated in FIG. 5, elastomeric sealing member 310 includes multiple sealing ridges 501, 502, and 503 that each form a respective air-tight seal against surface 513 and extend around perimeter 420 of IC 301. Thus, sealing ridge 502 forms air-tight seal 542 and sealing ridge 503 forms air-tight seal 543. In addition, elastomeric sealing member 310 forms an air-tight seal 544 against a surface 514 of packaging substrate 304. The multiple air-tight seals created by sealing ridges 501, 502, and 503 more reliably prevent excess or leaked TIM 307 (shown in FIG. 3) from leaking past elastomeric sealing member 310 than a single air-tight seal.

In some embodiments, the multiple sealing ridges of elastomeric sealing member 310 form one or more overflow cavities that can retain excess or leaked TIM 307 that has been forced past air-tight seal 541. For example, due to various deflections of IC 301 and packaging substrate 304 during thermal cycling of electronic device 300, a cavity 507 containing TIM 307 increases and decreases in volume, thereby causing a pumping action that can force TIM 307 past air-tight seal 541 during normal operation of electronic device 300. In some embodiments, elastomeric sealing member 310 includes multiple overflow cavities that can retain excess or leaked liquid metal or other TIM that is forced past air-tight seal 541. In the embodiment illustrated in FIG. 5, elastomeric sealing member 310 includes a first overflow cavity 551 that is disposed between sealing ridge 501 and sealing ridge 502 and a second overflow cavity 552 that is disposed between sealing ridge 502 and sealing ridge 503. In some embodiments, a volume of first overflow cavity 551 and/or second overflow cavity 552 is configured to be greater than an overflow volume of TIM 307 that can occur due to thermal cycling of electronic device 300. For example, in some embodiments, a tolerance stack up of various features of electronic device 300 can be employed to quantify a worst-case overflow volume of TIM 307. Factors considered in such a tolerance stack up can include a maximum expected error in total volume of TIM 307 applied to IC 301, a maximum expected deflection of IC 301 due to thermal cycling, a minimum expected deflection of IC 301 due to thermal cycling, a maximum expected deflection of packaging substrate 304 due to thermal cycling, a minimum expected deflection of packaging substrate 304 due to thermal cycling, a maximum expected coupling force applied to heatsink 303 in direction 309, and/or a minimum expected coupling force applied to heatsink 303 in direction 309, among others.

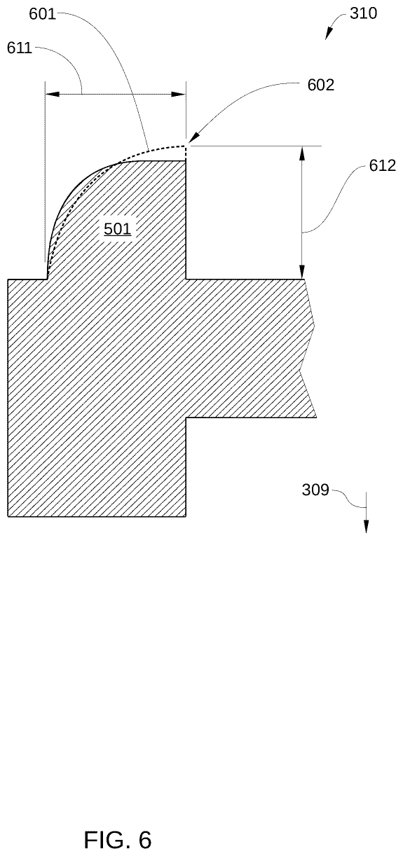

In some embodiments, one or more of sealing ridges 501, 502 and/or 503 is configured with an aspect ratio that facilitates the formation of an air-tight seal against surface 513 of heatsink 303. For example, in some embodiments, sealing ridge 501 is configured with an aspect ratio that prevents sealing ridge 501 from collapsing in a direction perpendicular to direction 309 when in a compressed state. One such embodiment is described below in conjunction with FIG. 6.

FIG. 6 is a conceptual cross-sectional view of sealing ridge 501 of elastomeric sealing member 310, according to various embodiments. In the embodiment illustrated in FIG. 6, sealing ridge 501 is shown in a compressed state, for example after heatsink 303 (shown in FIGS. 3 and 5) is coupled to IC package 360 (shown in FIG. 3) and is pressed against elastomeric sealing member 310 in direction 309. For reference, an uncompressed profile 601 (dashed lines) of sealing ridge 501 is also shown, indicating a location of a tip 602 of sealing ridge 501 prior to heatsink 303 being coupled to IC package 360.

According to various embodiments, sealing ridge 501 has an aspect ratio that prevents sealing ridge 501 from collapsing in a direction perpendicular to direction 309 when in a compressed state. In the embodiment illustrated in FIG. 6, a ratio of a width 611 of sealing ridge 501 to an uncompressed height 612 is at least 1.0. In such embodiments, sealing ridge 501 compresses in direction 309 as shown under load, rather than partially buckling or collapsing in a direction perpendicular to direction 309.

Returning to FIG. 5, in some embodiments, sealing ridge 501, sealing ridge 502 and/or sealing ridge 503 is configured to be a self-sealing air-tight seal. For example, in the embodiment illustrated in FIG. 5, sealing ridge 501 includes a first surface 561 facing IC 301 and a second surface 562 facing away from IC 301, where first surface 561 slopes away from IC 301 and packaging substrate 304 and toward tip 602 of first sealing ridge 501. Because first surface slopes away from IC 301, when excess liquid metal or thermal grease from TIM 307 is forced past airtight seal 541, for example during assembly and/or thermal cycling of electronic device 300, sealing ridge 501 is more likely to re-seat against surface 513 and reform air-tight seal 541. In the embodiment illustrated in FIG. 5, second surface 562 is substantially perpendicular to surface 513, but in other embodiments, second surface 562 can be angled.

In some embodiments, air-tight seal 544 against surface 514 of packaging substrate 304 is formed by elastomeric sealing member 310 being compressed against surface 514. In other embodiments, air-tight seal 544 is at least partially formed by an adhesive material 545 that is disposed between surface 514 and elastomeric sealing member 310. Adhesive material 545 can be any adhesive suitable for use with elastomeric sealing member 310 and packaging substrate 304. For example, in some embodiments, adhesive material 545 can be a high-temperature adhesive that does not degrade at the operating temperatures of electronic device 300.

In the embodiment illustrated in FIG. 5, electronic device 300 includes one or more electronic components 305 that are disposed on packaging substrate 304 and can be subject to shorting when contacted by TIM 307. To protect electronic components 305 from leaked and/or excessive TIM 307, elastomeric sealing member 310 includes one or more cavities 520. In such embodiments, elastomeric sealing member 310 includes a cavity 520 to accommodate each electronic component 305 or group of electronic components 305 disposed on packaging substrate 304.

As noted above, elastomeric sealing member 310 is configured to be positioned within opening 410 (shown in FIG. 4) formed in stiffener 306. In some embodiments, to prevent assembly issues during fabrication of electronic device 300, an inner dimension 571 of opening 410 is greater than a sum of a corresponding outer dimension 572 of elastomeric sealing member 310 and a manufacturing tolerance of the inner dimension 571. Thus, in such embodiments, elastomeric sealing member 310 outer dimension 572 is selected so that an outer edge of elastomeric sealing member 310 cannot overlap an inner edge 506 of stiffener 306 when elastomeric sealing member 310 is positioned within opening 410. Furthermore, in such embodiments, opening 410 can be employed as an assembly guide for the placement of elastomeric sealing member 310 onto packaging substrate 304.

In the embodiments described above, elastomeric sealing member 310 is employed in conjunction with IC package 360 (shown in FIG. 3), which is configured as a lidless IC package. Thus, in such embodiments, IC 301 is thermally coupled to heatsink 303 directly via TIM 307. In other embodiments, elastomeric sealing member 310 can be employed in conjunction with a lidded IC package. In such embodiments, IC 301 is thermally coupled to a protective lid via TIM 307, and the protective lid is then coupled to heatsink 303. For example, the protective lid may be a portion of stiffener 306 that extends over IC 301. In such embodiments, elastomeric sealing member 310 can be disposed around perimeter 420 of IC 301 or around a perimeter of the lidded IC package.

In sum, an elastic sealing member is included in an electronic device with one or more high-power ICs that are thermally coupled to a heatsink or other thermal solution. In some embodiments, an elastomeric sealing member is disposed around a perimeter of the one or more high-power ICs that can be shorted or damaged by leaked liquid-metal, graphene particles, or other materials originating with the TIM.

At least one technical advantage of the disclosed design relative to the prior art is that the disclosed design can prevent liquid-metal TIM or other electrically conductive TIM from leaking and contacting capacitors or other electrical components that are mounted on the same packaging substrate as a high-power chip that is thermally coupled to a thermal solution via the liquid-metal TIM. Another technical advantage is that the disclosed design can enable a thermal solution to be coupled to a high-power chip with greater pressure compared to using sealing materials that typically soften during operation of the high-power chip, such as wax-based substances, low-melting-point adhesives, and/or low-temperature “hot-melt” polymers. Yet another technical advantage is that the disclosed design can reduce the exposure of a liquid-metal TIM or other TIM to moisture and/or other contaminants that can react with and alter the thermal conductivity of the liquid-metal TIM. These technical advantages provide one or more technological advancements over prior art approaches.
1. In some embodiments, an electronic device includes: a printed circuit board; an integrated circuit that is coupled to the printed circuit board on a first side and a thermal solution on a second side; a thermal interface material that is disposed between the integrated circuit and the thermal solution; and an elastomeric sealing member that is disposed around a perimeter of the integrated circuit.
2. The electronic device of clause 1, wherein the thermal interface material includes one of a liquid metal, a thermal grease, or a graphene-based material.
3. The electronic device of clauses 1 or 2, wherein the elastomeric sealing member forms a continuous air-tight seal around the perimeter of the integrated circuit.
4. The electronic device of any of clauses 1-3, wherein the elastomeric sealing member forms a first air-tight seal against a surface of the thermal solution and a second air-tight seal against a surface of a packaging substrate that is coupled to the integrated circuit.
5. The electronic device of any of clauses 1-4, wherein the second air-tight seal is at least partially formed by an adhesive material disposed between the surface of the packaging substrate and the elastomeric sealing member.
6. The electronic device of any of clauses 1-5, wherein the elastomeric sealing member is disposed between the integrated circuit and an air gap between the surface of the thermal solution and a surface of an integrated-circuit package that includes the integrated circuit.
7. The electronic device of any of clauses 1-6, wherein the elastomeric sealing member comprises a first sealing ridge that forms a first air-tight seal around the perimeter of the integrated circuit.
8. The electronic device of any of clauses 1-7, wherein the elastomeric sealing member further comprises a second sealing ridge that forms a second air-tight seal around the perimeter of the first air-tight seal.
9. The electronic device of any of clauses 1-8, wherein a ratio of a width of the first sealing ridge to a height of the first sealing ridge is at least 1.0.
10. The electronic device of any of clauses 1-9, wherein the first sealing ridge has a first surface facing the integrated circuit and a second surface facing away from the integrated circuit, and wherein the first surface slopes away from the integrated circuit and a packaging substrate that is coupled to the integrated circuit and toward a tip of the first sealing ridge.
11. The electronic device of any of clauses 1-10, wherein the second surface is substantially perpendicular to a surface of the thermal solution that contacts the tip of the first sealing ridge.
12. The electronic device of any of clauses 1-11, wherein the elastomeric sealing member comprises: a first sealing ridge that forms a first air-tight seal around the perimeter of the integrated circuit; a second sealing ridge that forms a second air-tight seal around the perimeter of the first air-tight seal; and a cavity that is disposed between the first sealing ridge and the second sealing ridge.
13.The electronic device of any of clauses 1-12, wherein a volume of the cavity is greater than an overflow volume of thermal interface material that can occur due to thermal cycling of the electronic device.
14. The electronic device of any of clauses 1-13, wherein the thermal solution includes at least one of a heatsink, a vapor chamber, or a liquid cold plate.
15. The electronic device of any of clauses 1-14, wherein the elastomeric sealing member is disposed within an opening formed in a stiffener for an integrated-circuit package that includes the integrated circuit.
16. The electronic device of any of clauses 1-15, wherein an inner dimension of the opening is greater than a sum of a corresponding outer dimension of the elastomeric sealing member and a manufacturing tolerance of the inner dimension.
17. The electronic device of any of clauses 1-16, further comprising one or more electrical devices mounted on the printed circuit board, wherein the elastomeric sealing member includes a respective cavity that corresponds to each of the one or more electrical devices.
18. In some embodiments, a computing system includes: a memory; and an electronic device that includes: a printed circuit board; an integrated circuit that is coupled to the printed circuit board on a first side and a thermal solution on a second side; a thermal interface material that is disposed between the integrated circuit and the thermal solution; and an elastomeric sealing member that is disposed around a perimeter of the integrated circuit.
19. The computing system of clause 18, wherein the elastomeric sealing member forms a continuous air-tight seal around the perimeter of the integrated circuit.
20. The computing system of clauses 18 or 19, wherein the elastomeric sealing member comprises a first sealing ridge that forms a first air-tight seal around the perimeter of the integrated circuit.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

While the preceding is directed to embodiments of the present disclosure, other and further embodiments of the disclosure may be devised without departing from the basic scope thereof, and the scope thereof is determined by the claims that follow.

What is claimed is:

1. An electronic device, comprising:
a printed circuit board;
an integrated circuit that is coupled to the printed circuit board on a first side and a thermal solution on a second side;
a thermal interface material that is disposed between the integrated circuit and the thermal solution; and
an elastomeric sealing member that is disposed around a perimeter of the integrated circuit.

2. The electronic device of claim 1, wherein the thermal interface material includes one of a liquid metal, a thermal grease, or a graphene-based material.

3. The electronic device of claim 1, wherein the elastomeric sealing member forms a continuous air-tight seal around the perimeter of the integrated circuit.

4. The electronic device of claim 1, wherein the elastomeric sealing member forms a first air-tight seal against a surface of the thermal solution and a second air-tight seal against a surface of a packaging substrate that is coupled to the integrated circuit.

5. The electronic device of claim 4, wherein the second air-tight seal is at least partially formed by an adhesive material disposed between the surface of the packaging substrate and the elastomeric sealing member.

6. The electronic device of claim 4, wherein the elastomeric sealing member is disposed between the integrated circuit and an air gap between the surface of the thermal solution and a surface of an integrated-circuit package that includes the integrated circuit.

7. The electronic device of claim 1, wherein the elastomeric sealing member comprises a first sealing ridge that forms a first air-tight seal around the perimeter of the integrated circuit.

8. The electronic device of claim 7, wherein the elastomeric sealing member further comprises a second sealing ridge that forms a second air-tight seal around the perimeter of the first air-tight seal.

9. The electronic device of claim 7, wherein a ratio of a width of the first sealing ridge to a height of the first sealing ridge is at least 1.0.

10. The electronic device of claim 7, wherein the first sealing ridge has a first surface facing the integrated circuit and a second surface facing away from the integrated circuit, and wherein the first surface slopes away from the integrated circuit and a packaging substrate that is coupled to the integrated circuit and toward a tip of the first sealing ridge.

11. The electronic device of claim 10, wherein the second surface is substantially perpendicular to a surface of the thermal solution that contacts the tip of the first sealing ridge.

12. The electronic device of claim 1, wherein the elastomeric sealing member comprises:
a first sealing ridge that forms a first air-tight seal around the perimeter of the integrated circuit;
a second sealing ridge that forms a second air-tight seal around the perimeter of the first air-tight seal; and
a cavity that is disposed between the first sealing ridge and the second sealing ridge.

13. The electronic device of claim 12, wherein a volume of the cavity is greater than an overflow volume of thermal interface material that can occur due to thermal cycling of the electronic device.

14. The electronic device of claim 1, wherein the thermal solution includes at least one of a heatsink, a vapor chamber, or a liquid cold plate.

15. The electronic device of claim 1, wherein the elastomeric sealing member is disposed within an opening formed in a stiffener for an integrated-circuit package that includes the integrated circuit.

16. The electronic device of claim 15, wherein an inner dimension of the opening is greater than a sum of a corresponding outer dimension of the elastomeric sealing member and a manufacturing tolerance of the inner dimension.

17. The electronic device of claim 1, further comprising one or more electrical devices mounted on the printed circuit board, wherein the elastomeric sealing member includes a respective cavity that corresponds to each of the one or more electrical devices.

18. A computing system, comprising:
a memory; and
an electronic device that includes:
a printed circuit board;
an integrated circuit that is coupled to the printed circuit board on a first side and a thermal solution on a second side;
a thermal interface material that is disposed between the integrated circuit and the thermal solution; and
an elastomeric sealing member that is disposed around a perimeter of the integrated circuit.

19. The computing system of claim 18, wherein the elastomeric sealing member forms a continuous air-tight seal around the perimeter of the integrated circuit.

20. The computing system of claim 18, wherein the elastomeric sealing member comprises a first sealing ridge that forms a first air-tight seal around the perimeter of the integrated circuit.
